(19) United States
(12) Patent Application Publication
(10) Pub. No.: US 2014/0130850 A1
(43) Pub. Date: May 15, 2014

(54) COMPOSITION OF AN ORGANIC PHOTOVOLTAIC CELL OF A PHOTOVOLTAIC MODULE

(71) Applicants: Celia Nicolet, Talence (FR); Dargie H. Deribew, Nuremberg (DE); Cedric Renaud, Castanet-Tolosan (FR); Guillaume Fleury, Bordeaux (FR); Cyril Brochon, Merignac (FR); Laurence Vignau, Pessac (FR); Eric Cloutet, Saint-Caprais de Bordeaux (FR); Sébastien-Jun Mougnier, Paris (FR); Georges Hadziioannou, Leognan (FR)

(72) Inventors: Celia Nicolet, Talence (FR); Dargie H. Deribew, Nuremberg (DE); Cedric Renaud, Castanet-Tolosan (FR); Guillaume Fleury, Bordeaux (FR); Cyril Brochon, Merignac (FR); Laurence Vignau, Pessac (FR); Eric Cloutet, Saint-Caprais de Bordeaux (FR); Sébastien-Jun Mougnier, Paris (FR); Georges Hadziioannou, Leognan (FR)

(73) Assignees: ARKEMA FRANCE, Colombes (FR); INSTITUT POLYTECHNIQUE DE BORDEAUX, Talence Cedex (FR); CENTRE NATIONAL DE LA RECHERCHE SCIENTIFIQUE, Paris Cedex 14 (FR); UNIVERSITE DE BORDEAUX 1, Talence Cedex (FR)

(21) Appl. No.: 14/122,566

(22) PCT Filed: May 16, 2012
(86) PCT No.: PCT/FR2012/051102

§ 371 Date: Jan. 31, 2014

(30) Foreign Application Priority Data
May 27, 2011 (FR) 1154654
Nov. 18, 2011 (FR) 1160510

(51) Int. Cl. H01L 51/00; H01L 27/30

(52) U.S. Cl. CPC H01L 51/0043; H01L 27/301
USPC 136/251; 136/244; 252/511; 252/500

(57) ABSTRACT

A composition of an active film of an organic photovoltaic cell, including: an electron-donor material having a conjugated polymer; and an electron-acceptor material having a polymer, wherein the active film comprises a copolymer with a linear structure including: two to five blocks, at least two blocks of which have different chemical natures; two consecutive blocks having different chemical natures; each block having a molar mass of between 500 g/mol and 50,000 g/mol. Also, an organic-cell-based photovoltaic module incorporating such a composition and the use of this composition for the same purposes.

### FIELD OF THE INVENTION

A subject matter of the invention is a composition for an active layer of organic photovoltaic cells of a photovoltaic module exhibiting optimum properties for this application. The present invention also relates to the use of such a composition in organic photovoltaic cells of a photovoltaic module and to a photovoltaic module comprising such photovoltaic cells.

Global warming, linked to the greenhouse gases given off by fossil fuels, has led to the development of alternative energy solutions which do not emit such gases during their operation, such as, for example, photovoltaic modules. A photovoltaic module comprises a “photovoltaic cell”, this cell being capable of converting light energy into electricity.

Numerous types of photovoltaic panel structure exist.

Currently, use is predominantly made of “inorganic” photovoltaic panels, that is to say panels which operate with a board of semiconductors, generally of silicon, forming a photovoltaic cell for trapping the photons. By way of example, a photovoltaic cell conventionally comprises a plurality of individual cells, each individual cell comprising a photovoltaic sensor in contact with electron collectors placed above (upper collectors) and below (lower collectors) the photovoltaic sensor. When the photovoltaic cell is placed under a light source, it delivers a continuous electric current, which can be recovered at the terminals of the cell.

In addition to the inorganic photovoltaic cell, photovoltaic cells of organic type, that is to say that the photovoltaic cells are composed of organic materials, for example polymers, forming the “active layer”, are also known. Following the example of inorganic photovoltaic cells, these organic photovoltaic cells absorb the photons, bound electron-hole pairs (excitons) being generated and contributing to the photocurrent. The photovoltaic cell comprises two parts (subsequently referred to as “materials”), one exhibiting an excess of electrons (electron-donating material) and the other exhibiting a deficiency in electrons (electron-accepting material), referred to respectively as n-type doped and p-type doped.

The organic photovoltaic cell is less expensive, can be recycled and can be extended to flexible products or various conformations (for example building tiles), giving access to markets inaccessible to conventional technologies, in particular by their incorporation in multifunctional systems. Nevertheless, organic photovoltaic cells have suffered, to date, from a very low overall effectiveness level since the efficiency of such photovoltaic cells remains in practice far below 5%. Furthermore, currently, the lifetime of the photovoltaic cells is very limited.

### STATE OF THE ART

The mediocre performance and the mediocre lifetime of organic photovoltaic cells are directly related to a number of physicochemical parameters which currently present difficulties.

As has been seen above, an organic photovoltaic cell is composed of an electron-donating material and an electron-accepting material. In point of fact, a major technical problem is posed from the viewpoint of the control of the morphology of mixing of the electron-donating and electron-accepting materials.

Currently, in order to overcome this difficulty, the strategy consists in varying the annealing conditions in order to obtain the desired morphology. This annealing stage, which consists in heating the active layer for several minutes at temperatures of greater than approximately 100° C., is a stage which is virtually necessary in order to obtain the correct structure. The annealing stage exhibits the first disadvantage of being time consuming and thus expensive but also constitutes a limitation on the use of a flexible substrate (PET type) which cannot withstand excessively lengthy exposure to heat without experiencing a deterioration in the mechanical properties thereof. Several approaches have consisted in optimizing this stage by varying the operating conditions and it is also known, for example, from the document US 2009/0229667, that the addition of additives, such as alkanedithiols or alkyl halides, will act as plasticizer during the annealing which are capable of migrating but which do not make it possible to stabilize the morphologies. Nevertheless, if it is desired to obtain stable structures, it is necessary to introduce surfactants. In particular, it is known that there exist diblock or triblock copolymers having a conjugated sequence or diblock copolymers but not comprising any conjugated sequence. The document US 2008/0017244 is thus known but the block copolymers here act as transporter of charges (donor/receptor) and also as surfactant but do not solve the abovesaid first technical problem.

The document US2010/137518 is also known, which document provides for the addition, to the active layer, of a small amount of a diblock copolymer composed of an electron-donating block and of a second covalently grafted block with electron acceptors (fullerenes). This solution introduces improvements with regard to the efficiency but the synthesis of the additive is lengthy and complicated and no satisfactory result from the viewpoint of the stability over time and/or of the improvement in the efficiency without an annealing stage is obtained.

None of these existing solutions is very satisfactory regarding the control or the stabilization of the morphology of the mixing of electron-donating and electron-accepting materials.

Another major problem lies in the low effectiveness of the active layers of organic photovoltaic cells, which only very rarely exceed 5% efficiency. In point of fact, it is essential to increase this efficiency/effectiveness if it is desired to viably develop the photovoltaic applications.

Furthermore, there currently exists no additive capable of improving the efficiency or the stability of the organic solar cell and at the same time of eliminating the annealing stage.

### BRIEF DESCRIPTION OF THE INVENTION

The present invention is intended to solve the problems of the organic photovoltaic cells of photovoltaic modules of the prior art by providing a composition for an active layer of an organic cell comprising a copolymer having linear architecture of a specific type.

It has been found, by the applicant, after various experiments and handling operations, that a specific structure could alone exhibit optimum results making it possible to improve the compatibilization of a mixture between an electron-donating material and an electron-accepting material in an organic photovoltaic/solar cell, whether in terms of performance (energy efficiency) or in terms of stability (increased lifetime of the organic photovoltaic cell). Thus, the optimum structure of the active layer is obtained more easily and in a more lasting fashion (stabilized morphology) than for conventional processes (comprising one or more annealing stages). Specifically, it has also been shown that at least one of the examples of specific structure according to the invention makes it possible not only to improve the efficiency of the cell with respect to the reference but also to do it while dispensing with the annealing stage. This makes it possible to save time/lower the costs, in the manufacturing process, and to be able to prepare cells on flexible substrates without constraint due to the annealing temperature. The present invention thus relates to the improvement in each of the following properties/characteristics:

(a) effectiveness,

(b) manufacturing conditions,

(c) stability of organic photovoltaic cells by virtue of the action of a copolymer additive acting as compatibilizer and nanostructuring agent.

Thus, the present invention relates to a composition of an active layer of an organic photovoltaic cell comprising:
an electron-donating material consisting of a conjugated polymer;
an electron-accepting material;

characterized in that the active layer comprises a copolymer having linear architecture comprising:
from two to five blocks, including at least two blocks of different chemical nature;
two consecutive blocks being of different chemical nature;
each block exhibiting a molar mass of between 500 g/mol and 50 000 g/mol;
none of said blocks being bonded by a covalent bond to the electron-accepting material.

The expression “having a linear structure” is understood to mean the fact that the blocks of polymers forming the abovesaid copolymer stretch out, constituting a continuous chain of polymers exhibiting only two ends, in contrast to a three-dimensional structure, which exhibits at least three ends.

The expression “different chemical nature” is understood to mean the fact that the compounds or components do not belong to the same chemical family within the general group of thermoplastic polymers. By way of examples, a person skilled in the art distinguishes in particular the following chemical natures: polyamides, polyamideimides, saturated polyesters, polycarbonates, polyolefins (low- and high-density), polyestercarbonates, polyetherketones, polyestercarbonates, polyimides, polyketones, aromatic polyethers, and the like.

By virtue of the controlled structure of the copolymer having linear architecture according to the invention (number of blocks of polymers which are defined and low), one of the blocks will become located in the electron-donating material whereas the other polymer block of the copolymer will become located in the electron-accepting material (cf. FIGS. 3 and 4). Thus, the copolymer according to the invention acts as a particularly advantageous surfactant (minimization of the difference in energy existing between the electron-donating material and the electron-accepting material) by decreasing the size of the domains in each of the two materials, which renders the entire active layer more stable and thus better in performance.

Other advantageous characteristics of the invention are specified subsequently:
particularly advantageously, the abovesaid copolymer comprises a single block consisting of a conjugated polymer;
the conjugated polymer forming the electron-donating material and/or the abovesaid single block consisting of a conjugated polymer of the block copolymer consists of poly(3-hexylthiophene);
advantageously, the electron-accepting material consists of at least one fullerene, preferably methyl [6,6]-phenyl-C₆₁-butanoate (MPCB);
at least one of the blocks of the abovesaid copolymer consists of a polystyrene;
at least one of the blocks of the abovesaid copolymer consists of a polyalkyl acrylate, preferably poly(n-butyl acrylate), or of a polyisoprene;
at least one of the blocks of the abovesaid copolymer exhibits a Tg of less than 0° C., preferably of between −120° C. and −50° C.;
the block copolymer consists of poly(3-hexylthiophene-b-isoprene), poly(3-hexylthiophene-b-styrene) or poly(styrene-b-isoprene).

The invention relates to the use of the composition as described above in the organic photovoltaic cells of a photovoltaic module.

In addition, the invention also relates to a photovoltaic module exhibiting at least one layer forming an encapsulant comprising a photovoltaic cell, consisting of a plurality of individual organic photovoltaic cells each comprising an active layer capable of generating electrical energy, and a layer forming a back sheet, the composition of said active layer is as described above.

### DESCRIPTION OF THE APPENDED FIGURES

The description which will follow is given solely by way of illustration and without limitation with reference to the appended figures, in which:

FIG. 1 illustrates the photovoltaic efficiency (PCE) as a function of the mass fraction of copolymer in the active layer for two different examples of linear block copolymers;

FIG. 2 illustrates the standardized photovoltaic efficiency (standardized PCE) as a function of the illumination time;

FIG. 3 is a diagrammatic representation of a solar cell, the active layer consisting of a mixture of an electron-donating material and of an electron-accepting material; this diagram represents a type of cell tested in the context of this invention; under no circumstances is the invention limited to this type of cell, which is just an embodiment, and the invention can be applied to cells of any other type, in particular cells with an inverted structure with respect to this,

FIG. 4 is a diagrammatic representation of an interface between the two materials of the active layer which is stabilized by the block copolymer, this combination constituting the active layer according to the invention;

FIG. 5 is a graphical representation of the change in the photovoltaic efficiency as a function of the content of copolymer (P3HT-b-P4VP) added to the active layer.

### DETAILED DESCRIPTION OF THE INVENTION

The composition of the active layer according to the invention comprises, in its general definition:

an electron-donating material consisting of a conjugated polymer;

an electron-accepting material, such as, for example, a C₆₀ (fullerene) derivative; characterized in that the active layer comprises a copolymer having linear architecture comprising from two to five blocks, including at least two blocks of different nature, each having a molar mass of between 500 g/mol and 50 000 g/mol.

As regards the electron-donating material, it consists of a conjugated polymer.

The expression “conjugated polymer” is understood to mean conjugated polymers having a characteristic electronic structure referred to as “band structure”. These polymers are marked by the presence on the backbone of an alternation between double and single bonds.

Mention may be made, as nonlimiting examples of conjugated polymers, of polyacetylene, polypyrrole, polythiophene, polyphenylene and polyaniline but, more generally, the conjugated polymers bring together three main families:
poly(p-phenylene vinylene)s (PPVs), for example poly[2-methoxy-5-(2′-ethylhexyloxy)-1,4-phenylene vinylene] (MEH-PPV) or poly[2-methoxy-5-(3′,7′-dimethyloctyloxy)-1,4-phenylene vinylene] (MDMO-PPV);
polythiophenes (PTs) resulting from the polymerization of thiophenes and which are sulfur heterocycles, for example poly(3-hexylthiophene) (P3HT);
polyfluorenes, for example poly[2,7-(9,9-dioctylfluorene)-alt-5,5-(48,78-di-2-thienyl-28,18,38-benzothiadiazole)] (PFDTBT).

Among all the conjugated polymers which can be chosen to participate in the composition according to the present invention, the applicant company has a preference for poly(3-hexylthiophene) (P3HT).

The preparation of a conjugated polymer is well known to a person skilled in the art.

Mention will be made, by way of example, of the synthesis of poly(3-hexylthiophene), which is copiously described in the literature. Furthermore, this polymer is commercially available.

As regards the electron-acceptor material, it consists of a molecule capable of accepting electrons.

Preferably, the electron-accepting material will be chosen as being a fullerene or a mixture of fullerenes (C₆₀). More preferably still, methyl [6,6]-phenyl-C₆₁-butanoate (MPCB, a compound known to a person skilled in the art and already commercially available) will be chosen for the electron-accepting material.

As regards the block copolymer, it has a linear architecture, that is to say a linking together of at least two different blocks (or sequences). Of course, the order of the blocks indicated below is given only by way of indication and does not necessarily reflect the true order of linking together, it being possible for these blocks to be inverted at will.

The first block consists of a nonconjugated polymer having a conventional structure of vinyl (and in particular styrene, acrylic or methacrylic), saturated polyolefin or unsaturated polyolefin type. Preferably, this first block of the copolymer having linear architecture will be chosen as being polystyrene (PS) or polyisoprene (PI).

As regards the second polymer block of the copolymer having linear architecture, it consists of a different polymer from that of the first block which can either be nonconjugated, with a conventional structure, of vinyl (and in particular styrene, acrylic or methacrylic) saturated polyolefin or unsaturated polyolefin type or can be a semiconducting conjugated polymer. In the latter case, where the second block consists of a conjugated polymer, no other block of the copolymer can consist of an identical or nonidentical conjugated polymer.

Preferably, this second block of the copolymer having linear architecture will be chosen as being polyisoprene (PI), polystyrene (PS) or poly(3-hexylthiophene) (P3HT).

As regards the possible following blocks (third, fourth and fifth blocks) of the copolymer having linear architecture, if appropriate, they consist of a different polymer from that of the first block, with an exclusively nonconjugated structure, of vinyl (and in particular styrene, acrylic or methacrylic), saturated polyolefin or unsaturated polyolefin type. In the invention, it is particularly important for two consecutive blocks to be different.

Preferably, the third, fourth and fifth blocks different from the second block of the copolymer having linear architecture will also be chosen as being polyisoprene (PI), polystyrene (PS), a polystyrene derivative, such as poly(4-vinylpyridine) (P4VP), or a polyalkyl acrylate. Of course, the invention provides for there only to be two blocks and the addition of a third, fourth and fifth block is only optional.

The following copolymers may be found as nonlimiting example of the copolymer having linear architecture according to the invention:

poly(styrene-b-methyl methacrylate) (PS-PMMA)

poly(styrene-b-butadiene) (PS-PB)

poly(styrene-b-isoprene) (PS-PI)

poly(styrene-b-(2-vinylpyridine)) (PS-P2VP)

poly(styrene-b-(4-vinylpyridine)) (PS-P4VP)

poly(ethylene-b-ethylethylene) (PE-PEE)

poly(ethylene-b-ethylpropylene) (PE-PEP)

poly(ethylene-b-styrene) (PE-PS)

poly(ethylene-b-butadiene) (PE-PB)

poly(styrene-b-butadiene-b-styrene) (PS-PB-PS)

poly(styrene-b-isoprene-b-styrene) (PS-PI-PS)

poly(styrene-b-ethylene-b-styrene) (PS-PE-PS)

poly(styrene-b-(ethylene-co-butylene)-b-styrene) (PS-PEB-PS)

poly(styrene-b-butadiene-b-methyl methacrylate) (PS-PB-PMMA)

poly((2-vinylpyridine)-b-isoprene-b-styrene) (P2VP-PI-PS)

poly(ethylene oxide-b-propylene oxide-b-ethylene oxide) (PEO-PPO-PEO)

poly(styrene-b-acrylic acid) (PS-PAA)

poly(styrene-b-ethylene oxide) (PS-PEO)

multiblocks of the type poly(ether-b-ester); poly(amide-b-ether); polyurethanes.

Nevertheless, for the block copolymer of the invention, the choice will preferably be made of the following copolymers:

poly(3-hexylthiophene-b-isoprene) (P3HT-b-PI): example No. 1

poly(3-hexylthiophene-b-styrene) (P3HT-b-PS): example No. 2

poly(styrene-b-isoprene) (PS-b-PI): example No. 3

poly(3-hexylthiophene-b-(4-vinylpyridine)) (P3HT-b-P4VP): example No. 4

According to one possibility offered by the invention, as mentioned above, one of the blocks of the copolymer (the second block) can consist of a conjugated polymer. This option (which corresponds to the preferred examples 1 and 2) is, as will be seen subsequently, particularly advantageous, in particular from the viewpoint of the efficiency or of the effectiveness of the active layer of the organic photovoltaic cell.

The manufacture of the copolymer having a linear structure comprising from two to five blocks is carried out in a conventional manner well known to a person skilled in the art. Mention will be made, as nonlimiting examples, of anionic polymerization, controlled radical polymerization, or polyaddition or condensation.

As regards the three examples of preferred copolymers, they can be obtained according to the following processes:

### Synthesis of P3HT-b-PI

### Example 1

The synthesis of P3HT-b-PI consists of the deactivation of living polyisoprene (PI) synthesized by anionic polymerization, which is well known to a person skilled in the art, on P3HT functionalized with bromine at the chain end, which is also well known to a person skilled in the art (McCullough, Macromolecules, 2005), in the presence of lithium methoxyethanol, which increases the reactivity of the polyisoprenyl ion by breaking the polyisoprenyllithium aggregates. This operation is carried out in an anhydrous solvent and under a controlled atmosphere (vacuum, nitrogen or argon) according to a process well known to a person skilled in the art.

### Synthesis of P3HT-b-PS

### Example 2

P3HT-b-PS can be synthesized via two routes. The first is a “click chemistry” coupling (Huisgen azide-alkyne cycloaddition) between alkyne-terminated P3HT and polystyrene (PS) synthesized by ATRP with an azide-functionalized initiator already described in the literature (Urien, M., Erothu, H., Cloutet, E., Hiorns, R. C., Vignau, L. and Cramail, H., Macromolecules, 2008, 41(19), 7033-7040). The second route consists of the deactivation of the living PS synthesized by anionic polymerization (this operation being well known to a person skilled in the art) on P3HT functionalized with aldehyde at the chain end, the synthesis of which is described in the literature (Iovu, M. C., Jeffries-El, M., Mang, R., Kowalewski, T. and McCullough, R. D., J. Macromol. Sci., Part A: Pure Appl. Chem., 2006, 43(12), 1991-2000). The operating conditions are the same as for example 1.

### Synthesis of the copolymer PS-b-PI

### Example 3

The copolymer PS-b-PI is synthesized by anionic polymerization initiated by sec-butyllithium with sequential addition of the monomers (first the styrene and then the isoprene), as is well known to a person skilled in the art (Fetters, L. J., Luston, J., Quirk, R. P., Vass, F., N., Y. R., Anionic Polymerization, 1984).

### Synthesis of P3HT-b-P4VP

### Example 4

The synthesis of the monomer 2,5-dibromo-3-hexylthiophene is known to a person skilled in the art. The synthesis of ω-allyl-terminated poly(3-hexylthiophene) is known to a person skilled in the art. The synthesis of ω-hydroxyl-terminated poly(3-hexylthiophene) is known to a person skilled in the art.

The synthesis of ω-acrylate-terminated poly(3-hexylthiophene) is carried out as follows:

280 mg of ω-hydroxyl-terminated P3HT with a mass Mₙ=2000 g.mol⁻¹ (0.14 mmol) have to be introduced under a stream of molecular nitrogen into a two-necked round-bottomed flask, dried beforehand with a paint burner under vacuum, with a molecular nitrogen/vacuum outlet and surmounted by a burette of freshly distilled tetrahydrofuran (THF). It is subsequently necessary to carry out three vacuum/molecular nitrogen cycles, then to leave the round-bottomed flask under vacuum and to add 50 ml of THF. Finally, the mixture has to be left to stir at 40° C. for at least 30 min in order for complete dissolution of the polymer to take place. Subsequent to this stage, the mixture has to be brought back to ambient temperature and then 2.2 ml of triethylamine (15.5 mmol) have to be added under a stream of molecular nitrogen using a purged syringe. Subsequently, it is necessary to leave stirring for 15 minutes in order to then cool the reaction medium to 0° C. Finally, the acryloyl chloride then has to be added dropwise via a purged syringe. It is then necessary to leave stirring for 24 hours while allowing the reaction medium to return to ambient temperature. At the end of the reaction, the polymer is precipitated from cold methanol (500 ml). At the end, as final stage, it is necessary to filter and then dry the product under vacuum at ambient temperature for 48 hours.

The synthesis of ω-Blocbuilder®-terminated poly(3-hexylthiophene) is carried out as follows:

100 mg of ω-acrylate-terminated P3HT with a mass Mₙ=2000 g.mol⁻¹ (0.05 mmol) and 300 mg of Blocbuilder® (0.79 mmol, 16 equivalents) are introduced into a Schlenk tube with a molecular nitrogen/vacuum outlet. A graduated burette filled beforehand with degassed toluene is placed above the Schlenk tube. Three vacuum/molecular nitrogen cycles are carried out in order to thoroughly remove the molecular oxygen present in the reaction medium and then 2 ml of toluene are added. The mixture is left stirring at 40° C. for 15 min in order to dissolve. The Schlenk tube is subsequently placed in an oil bath preheated to 80° C. and the mixture is left stirring for 2 h. At the end of the reaction, the Schlenk tube is placed in liquid nitrogen until the reaction medium has returned to ambient temperature. The product obtained is precipitated from 15 ml of cold methanol in order to remove the excess of Blocbuilder®. This operation is repeated twice. The product is subsequently filtered off and then dried under vacuum at 40° C. overnight in order to remove any trace of solvent (toluene and methanol). The macroinitiator thus obtained is stored in a refrigerator.

Finally, the synthesis of the copolymer poly(3-hexylthiophene)-block-poly(4-vinylpyridine) is carried out as follows:

47 mg of ω-Blocbuilder®-terminated P3HT with a mass Mₙ=2000 g.mol⁻¹ (0.024 mmol) are introduced in a Schlenk tube with a molecular nitrogen/vacuum outlet. A graduated burette filled beforehand with distilled 4-vinylpyridine is placed above the Schlenk tube and then three vacuum/molecular nitrogen cycles are carried out in order to remove the molecular oxygen present in the reaction medium. 2 ml of 4-vinylpyridine (2 g, 800 equivalents) are added and then the mixture is left stirring at 40° C. for 1 hour in order to dissolve. The Schlenk tube is subsequently placed in an oil bath preheated to 115° C. and the mixture is left stirring for 5 min. The Schlenk tube is put in liquid nitrogen in order to halt the polymerization. Once at ambient temperature, the copolymer is precipitated from 20 ml of cold diethyl ether. It is filtered off and then dried under vacuum at 90° C. for 24 hours in order to remove the residual monomers.

An implementational example of the formulation claimed by the present invention consists of the following process with P3HT as donating material and MPCB as accepting material:

Different amounts of copolymers (from 0 to 10% by weight, with respect to the amount of dry matter) are introduced into a solution of P3HT/MPCB (1/1 by weight mixture, overall concentration of 40 mg.ml⁻¹) in ortho-dichlorobenzene. The solutions thus prepared are then left stirring at 50° C. (degrees Celsius) for 16 hours in order to have complete dissolution. The solution thus obtained (filtered using a polytetrafluoroethylene (PTFE) membrane with pores having a diameter of 0.2 μm) is subsequently deposited by spin coating onto the appropriate substrate and under inert atmosphere. The thickness of the active layer thus obtained is between 80 and 100 nm (nanometers).

Finally, it should be noted that the composition of the active layer according to the invention advantageously incorporates small molecules which are characterized by their low molecular weight which does not exceed a few thousand units of atomic mass. After the fashion of the conjugated polymers, these small molecules are electron acceptors or donors, which makes it possible for the latter to also facilitate the transportation of electric charges and to be capable of forming excitons with the conjugated polymers.

These small molecules are generally added to the composition by dissolution in the mixture comprising the other components (polymers).

Mention will be made, as examples of these small molecules, of:
fullerene (C₆₀), which is a compound formed of 60 carbon atoms and which has a spherical shape close to that of a soccer ball. This molecule is preferred here as additive in the composition according to the invention;
methyl [6,6]-phenyl-C₆₁-butanoate (MPCB), which is a fullerene derivative having a chemical structure which has been modified in order to render it soluble;
carbon nanotubes and graphenes;

perylene, consisting of an aromatic nucleus of hydrocarbons of chemical formula C₂₀H₁₂, for example N,N′-dimethyl-3,4,9,10-perylenetetracarboxylic diimide (PTCDI) (perylene derivative with two nitrogen atoms, two oxygen atoms and two methyl groups CH₃), or perylene-3,4,9,10-tetracarboxylic dianhydride (PTCDA) (perylene derivative with six oxygen atoms).

In the photovoltaic modules, as UV radiation is capable of resulting in a slight yellowing of the composition used, UV stabilizers and UV absorbers, such as benzotriazole, benzophenone and the other hindered amines, can be added in order to ensure the transparency of the encapsulant during its lifetime. These compounds can, for example, be based on benzophenone or on benzotriazole. They can be added in amounts of less than 10% by weight and preferably from 0.1% to 5% by weight of the total weight of the composition.

It will also be possible to add antioxidants in order to limit the yellowing during the manufacture of the encapsulant, such as phosphorus-comprising compounds (phosphonites and/or phosphites) and hindered phenolic compounds. These antioxidants can be added in amounts of less than 10% by weight and preferably from 0.1% to 5% by weight of the total weight of the composition.

Flame-retarding agents can also be added. These agents may or may not be halogenated. Mention may be made, among halogenated agents, of brominated products. Use may also be made, as non-halogenated agent, of phosphorus-based additives, such as polyphosphate, phosphinate or pyrophosphate, ammonium phosphate, melamine cyanurate, pentaerythritol, zeolites and the mixtures of these agents. The composition can comprise these agents in proportions ranging from 3% to 40%, with respect to the total weight of the composition.

If this is desired in a specific application, it is also possible to add pigments, such as, for example, coloring or brightening compounds, in proportions generally ranging from 5% to 15% with respect to the total weight of the composition.

As regards the other aspects of the invention relating to the use of the composition according to the invention in a photovoltaic module, a person skilled in the art may refer, for example, to the Handbook of Photovoltaic Science and Engineering, Wiley, 2003, volume 7.

It should be noted that the composition of the active layer according to the present invention can also be used in fields other than that of photovoltaics, on each occasion that this active layer is used in its first function, namely to convert solar energy into electrical energy.

### Materials Employed to Form the Test Formulations:

In the following, tests on compositions according to the invention are presented, in connection with the appended figures, which demonstrate that these compositions are satisfactory from the viewpoint of the technical problems set out above, namely, essentially:

1. use of the copolymer as compatibilizer introducing an improvement to the effectiveness/efficiency of the active layer by optimization of its morphology (problem 1);

2. use of the copolymer as compatibilizer introducing an improvement in the effectiveness/efficiency, without an annealing stage, of the active layer by spontaneous optimization of its morphology (problem 1a);

3. increase in the lifetime of the cell by virtue of the stabilization of the active layer by the copolymer (problem 2).

### 1. Use of the Copolymers Having Linear Architecture According to the Invention as Compatibilizer of the Active Layer (Abovementioned Problem 1):

Production of the Test Formulations and Films:

All the cells were prepared and tested under a controlled atmosphere (absence of oxygen and of moisture) in the following way:

Different amounts of copolymers (0% to 10% by weight, with respect to the P3HT/MPCB amount) are introduced into a solution of P3HT/MPCB (1/1 by weight mixture, overall concentration of 40 mg.ml⁻¹) in ortho-dichlorobenzene. The solutions thus prepared are then left stirring at 50° C. (degrees Celsius) for 16 hours in order to have complete dissolution. Furthermore, the ITO (indium oxide In₂O₃ doped with tin) on glass substrates are washed in an ultrasonic bath. This is carried out, in a first step, in acetone, then in ethanol and finally in isopropanol. Each washing operation lasts fifteen minutes. After having dried and treated the substrate with UV/ozone for fifteen minutes, a thin layer of PEDOT-PSS (poly(3,4-ethylenedioxythiophene)=PEDOT and poly(sodium styrenesulfonate)=PSS) was deposited by the spin coating technique well known to a person skilled in the art at a speed of five thousand revolutions per minute (5000 rev/min) and subsequently dried in an oven at 110° C. under dynamic vacuum. The thickness of the PEDOT-PSS layer is 50 nm (nanometers). It was measured, for example, using an “Alpha-step IQ Surafe Profiler” device. The active layer, composed of a P3HT:MPCB:copolymer mixture dissolved beforehand in ortho-dichlorobenzene at 50° C., is deposited on this substrate by spincoating on the PEDOT/PSS layer at a speed of one thousand revolutions per minute (1000 rev/min). The thickness of this layer is typically between 80 and 150 nm. An aluminum (Al) cathode is deposited by thermal evaporation under vacuum (˜10⁻⁷ mbar) through a mask. The active surface area of the cell is thus 8.4 mm². A heat treatment at 165° C. for 20 min is then applied via a heating plate.

A standard configuration (ITO/PEDOT:PSS/P3HT:MPCB:copolymer/Al) for a photovoltaic cell is then obtained. The electrical contacts with the cells are subsequently established using a “Karl Suss PM5” sampler. The current/voltage measurements are acquired by using, for example, a “Keithley 4200 SCS” under an illumination of 100 mW/cm² obtained via a “K.H.S. Solar Celltest 575” solar simulator in combination with AM 1.5 G filters. All the procedures carried out after the deposition of the PEDOT-PSS layer were carried out in a glove box under an inert atmosphere (molecular nitrogen) with an amount of water and molecular oxygen of less than 0.1 ppm (part per million).

Tests Carried Out on the Films:

The current/voltage measurements obtained by using a “Keithley 4200 SCS” under an illumination of 100 mW/cm² make it possible to obtain the optoelectronic characteristics of the cells produced according to the above protocol. The photovoltaic efficiencies (PCEs) for different active layer compositions (copolymer use, different compositions by weight of the active layer in P3HT, MPCB and copolymer) are extracted from this data. The results of these characterizations are summarized in FIG. 1.

Results of the Tests Carried Out:

A significant improvement in the photovoltaic efficiencies (up to 30%) was found for the addition of an optimized mass fraction of linear block copolymers to the active layer (cf. FIG. 1). The best result was obtained with the addition of a mass fraction equal to 7% of linear block copolymers of P3HT-b-PI architecture (copolymer of example No. 1) to the P3HT:MPCB active layer. A photovoltaic efficiency of 4.6±0.2% was obtained by using this formulation, which is to be compared with the PCE (state of the art, reference sample) of 3.5±0.4% obtained for the nonformulated P3HT:MPCB active layer.

2) Use of the Copolymers Having Linear Architecture According to the Invention as Compatibilizer and Direct Nanostructuring Agent of the Active Layer without Other Process (Abovementioned Problem 1a):

Production of the Test Formulations and Films:

The glass/ITO substrates (8.4 mm²) are successively cleaned with acetone, with ethanol and with isopropanol in an ultrasonic bath for 15 min each. A layer of a solution of titanium(IV) isopropoxide stabilized with hydrochloric acid and diluted in ethanol is subsequently deposited by spin coating above the ITO layer. The cell is left in contact with the air at ambient temperature for 1 hour in order to convert the precursor into TiOₓ. The active layer is subsequently deposited. The solution consists of P3HT (Plextronix), MPCB (Solaris) and a certain percentage of the P3HT-b-P4VP copolymer (from 0% to 10%). The block copolymer used in this example has P3HT and P4VP blocks with respective molar masses of 2500 g/mol and 5000 g/mol. Finally, an MoO₃ layer and also the electrode (silver) are deposited by thermal evaporation.

Tests Carried Out on the Films:

The current/voltage measurements obtained by using a “Keithley 4200 SCS” under an illumination of 100 mW/cm² make it possible to obtain the optoelectronic characteristics of the cells produced according to the above protocol. The photovoltaic efficiencies (PCEs) for different active layer compositions (copolymer use, different compositions by weight of the active layer in P3HT, MPCB and copolymer) are extracted from this data.

Results of the Tests Carried Out:

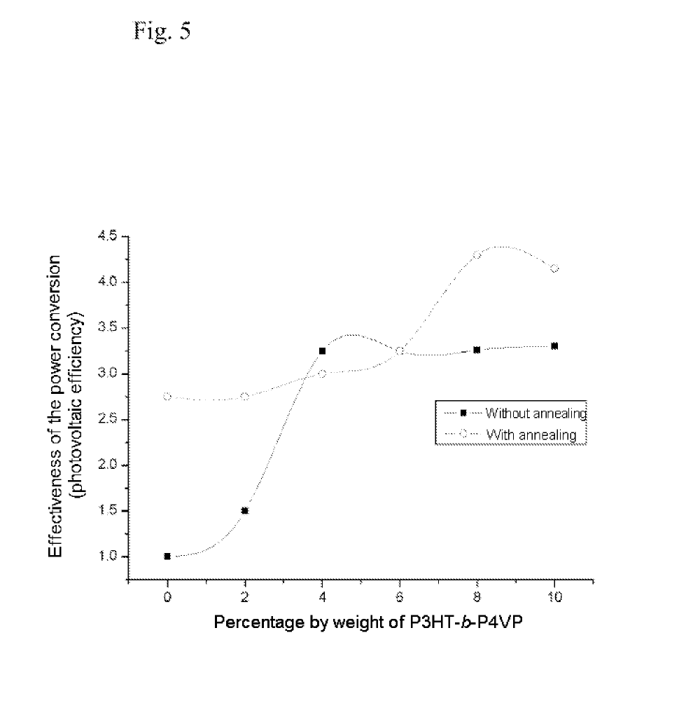

The different compositions were measured before and after a stage of annealing for a few minutes at 160° C. The results are presented in the following table and also in FIG. 5 (appended).

TABLE 1
photovoltaic efficiency as a function of the content of copolymer
added to the active layer

| % by weight of P3HT-b-P4VP | 0^{(a)} | 2 | 4 | 6 | 8 | 10 |
|---|---|---|---|---|---|---|
| Efficiency without annealing | 1.00 | 1.50 | 3.25 | 3.25 | 3.26 | 3.33 |
| (%) | | | | | | |
| Efficiency with annealing (%) | 2.75 | 2.75 | 3.00 | 3.25 | 4.30 | 4.15 |

^{(a)}reference cell comprising only the P3HT/MPCB mixture in the active layer

As above, an improvement in the efficiency of the cell after annealing is clearly observed: the efficiency changes from 2.75% to 4.30% when 8% of copolymer are added to the active layer.

However, the efficiency is also improved before the annealing stage. Thus, an efficiency of 3.25% is obtained without annealing, when at least 4% of copolymer are added, which is greater than the reference cell after annealing.

The results from the table and from the appended FIG. 5 clearly show an improvement in the efficiency and manufacturing process conditions.

### 3) Improvement in the Effectiveness/Efficiency of the Active Layer of Organic Photovoltaic Cells (Abovementioned Problem 2):

Production of the Test Formulations and Films:

Glass substrates covered with indium/tin oxide (ITO) are washed in an ultrasonic bath. This is carried out, in a first step, in acetone, then in ethanol and finally in isopropanol. After drying, a UV/ozone treatment is applied to these substrates for fifteen minutes and a thin layer of PEDOT/PSS (approximately 50 nanometers) is deposited by spin coating and then dried under vacuum at 110° C. for one hour. All the stages taking place after the deposition of the PEDOT/PSS layer are carried out under an inert atmosphere in a glove box (O₂ and H₂O<0.1 ppm). The active layer, composed of a P3HT:MPCB:copolymer mixture dissolved beforehand in ortho-dichlorobenzene at 50° C., is deposited on this substrate by spin coating on the PEDOT/PSS layer. The thickness of this layer is typically between 100 and 150 nm. An aluminum (Al) cathode is then deposited by thermal evaporation under vacuum (˜10⁻⁷ mbar) through a mask. The active surface area of the cell is thus 8.4 mm².

A heat treatment on a heating plate at 165° C. is then applied for twenty minutes. A standard configuration (ITO-PEDOT:PSS/P3HT:MPCB:copolymer/A1) for a photovoltaic cell is then obtained. The electrical contacts with the cells are subsequently established by using, for example, a “Karl Suss PM5” sampler. The current/voltage measurements are acquired by using a “Keithley 4200 SCS” under an illumination of 100 mW/cm² obtained via a “K. H. S. Solar Celltest 575” solar simulator in combination with AM 1.5 G filters. The cells were characterized before the beginning of the degradation cycle in order to make sure of the same level of initial performance of the photovoltaic cells tested.

Tests Carried Out on the Films:

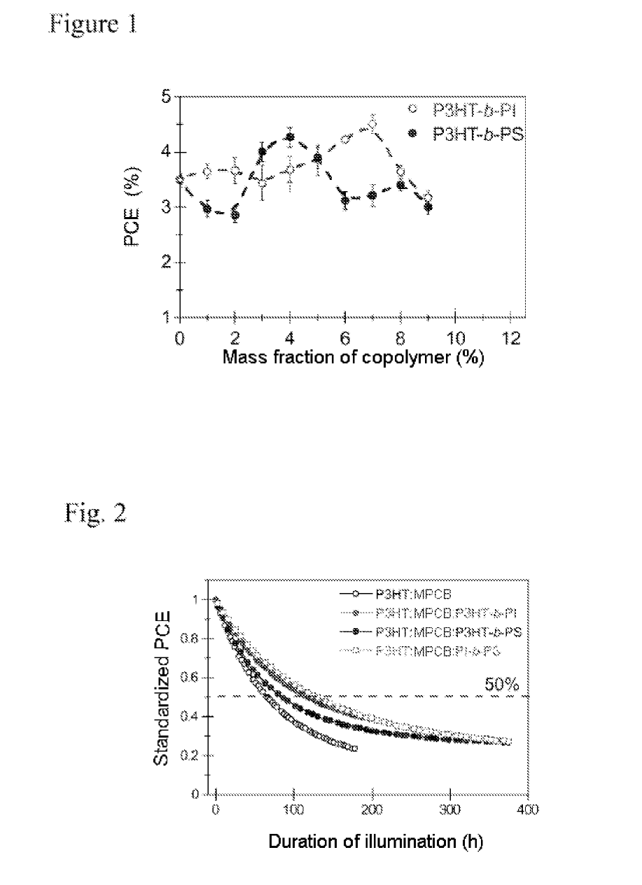

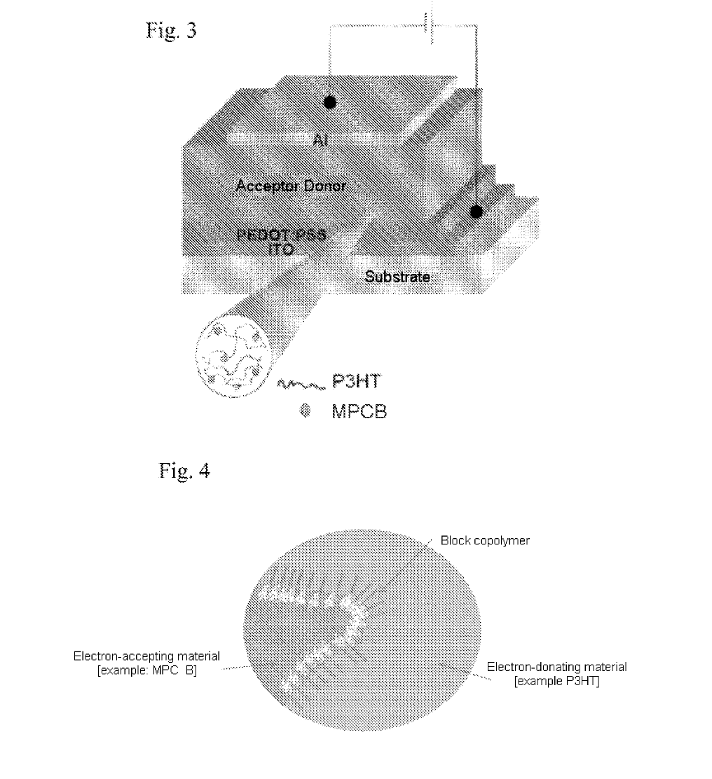

The stability tests and measurements of lifetime were carried out on the cells comprising the P3HT:MPCB:copolymer system. In order to do this, the photovoltaic cells are placed under “standard” conditions of illumination in a glove box in an inert atmosphere. This illumination standard is defined by an AM 1.5 G spectrum (inclination of the sun of 45°) and by a light power of the order of 100 mW/cm². Under illumination, the solar cells are subjected to a constant temperature of 55° C. caused the heating of the glazing of the solar simulator, thus resulting in an accelerated aging of the organic photovoltaic cells. The lifetime of the solar cells operating at ambient temperature can then be estimated from these measurements. FIG. 2 reports the change in the PCE as a function of the duration of illumination and thus makes it possible to evaluate the improvement in the stability and in the lifetime of the organic photovoltaic cells for different linear block copolymers under AM 1.5 G illumination at 25° C.

Results of the Tests Carried Out:

A significant improvement in the lifetime of the organic photovoltaic cells (lifetime doubled in the case of the addition of PI-b-PS) was found with the addition of an optimized mass fraction of linear block copolymers to the active layer (cf. FIG. 2). The best result was obtained with the addition of a mass fraction equal to 5% of linear block copolymers of PI-b-PS architecture to the P3HT:MPCB active layer, for which the lifetime of the photovoltaic cell was doubled.

1. A composition of an active layer of an organic photovoltaic cell comprising:
an electron-donating material consisting of a conjugated polymer;
an electron-accepting material;
wherein the active layer comprises a copolymer having linear architecture comprising:
from two to five blocks, including at least two blocks of different chemical nature;
two consecutive blocks being of different chemical nature;
each block exhibiting a molar mass of between 500 g/mol and 50 000 g/mol;
none of said blocks being bonded by a covalent bond to the electron-accepting material.

2. The composition as claimed in claim 1, wherein the copolymer comprises a single block consisting of a conjugated polymer.

3. The composition as claimed in claim 2, wherein the conjugated polymer forming the electron-donating material and/or the single block consisting of a conjugated polymer of the block copolymer consists of poly(3-hexylthiophene).

4. The composition as claimed in claim 1, wherein the electron-accepting material consists of at least one fullerene.

5. The composition as claimed in claim 1, wherein at least one of the blocks of the copolymer consists of a polystyrene.

6. The composition as claimed in claim 1, wherein at least one of the blocks of the copolymer consists of a polyalkyl acrylate or of a polyisoprene.

7. The composition as claimed in claim 1, wherein at least one of the blocks of the copolymer exhibits a Tg of less than 0° C.

8. The composition as claimed in claim 1, wherein the copolymer consists of poly(3-hexylthiophene-b-isoprene), poly(3-hexylthiophene-b-styrene), poly(styrene-b-isoprene) or poly(3-hexylthiophene-b-(4-vinylpyridine)).

9. A photovoltaic module comprising the composition as claimed in claim 1 in the organic photovoltaic cells of the photovoltaic module.

10. A photovoltaic module exhibiting at least one layer forming an encapsulant comprising a photovoltaic cell, the photovoltaic module consisting of a plurality of individual organic photovoltaic cells each comprising an active layer capable of generating electrical energy, and a layer forming a back sheet, the composition of said active layer is as claimed in claim 1.

11. The composition as claimed in claim 1, wherein the electron-accepting material consists of methyl [6,6]-phenyl-C₆₁-butanoate (MPCB).

12. The composition as claimed in claim 1, wherein at least one of the blocks of the copolymer consists of poly(n-butyl acrylate).

13. The composition as claimed in claim 1, wherein at least one of the blocks of the copolymer exhibits a Tg of between −120° C. and −50° C.
